(19) United States
(12) Patent Application Publication
(10) Pub. No.: US 2024/0333217 A1
(43) Pub. Date: Oct. 3, 2024

(54) OUTPUT AMPLIFIER CIRCUIT, DISPLAY DRIVER, AND DISPLAY DEVICE

(71) Applicant: LAPIS Technology Co., Ltd., Yokohama (JP)

(72) Inventor: Hiroshi TSUCHI, Yokohama (JP)

(73) Assignee: LAPIS Technology Co., Ltd., Yokohama (JP)

(21) Appl. No.: 18/607,530

(22) Filed: Mar. 17, 2024

(30) Foreign Application Priority Data
Mar. 28, 2023 (JP) 2023-050711

(51) Int. Cl. H03F 1/02; G09G 3/20; H03F 3/04

(52) U.S. Cl. CPC H03F 1/0205; G09G 3/2007; H03F 3/04; G09G 2310/0291; G09G 2330/021; G09G 2330/028

(57) ABSTRACT

An output amplifier circuit includes: 1st to K-th sub-bias circuits configured to be disposed in correspondence with 1st to K-th amplifier groups acquired by dividing 1st to n-th amplifiers for every predetermined number of amplifiers, generate a plurality of bias voltages for setting current values of operation currents of the amplifiers, and supply the bias voltages to amplifiers belonging to corresponding amplifier groups; and a main bias circuit configured to supply K currents having current values corresponding to voltage values designated by a control signal designating the voltage values of bias voltages to the 1st to K-th sub-bias circuits as 1st to K-th bias control currents, in which the 1st to K-th sub-bias circuits generate the plurality of bias voltages based on voltages acquired by performing current-to-voltage conversion on the bias control currents received by the sub-bias circuits among the 1st to K-th bias control currents.

### CROSS-REFERENCE TO RELATED APPLICATION

This application claims the priority benefits of Japanese application no. 2023-050711, filed on Mar. 28, 2023. The entirety of the above-mentioned patent application is hereby incorporated by reference herein and made a part of this specification.

### BACKGROUND

### Technical Field

The disclosure relates to an output amplifier circuit including a plurality of amplifiers and a display driver and a display device including this output amplifier circuit.

### Description of Related Art

In a display driver, for example, driving a liquid crystal display panel or an organic EL panel as a display panel, a plurality of output amplifiers each amplifying a grayscale voltage corresponding to a luminance level represented by a video signal and supplying a resultant voltage to a source line of the display panel are included.

In accordance with an increase in the sizes of screens and high accuracy of recent display panels, shortening of a rising edge time or a falling edge time of an output voltage, a so-called high slew rate, is desirable for an output amplifier. Meanwhile an output amplifier, for example, is formed from an operational amplifier, and thus, although the slew rate can be raised by increasing an operation current flowing through its differential stage, there is a problem in that the amount of power consumption increases accordingly.

Thus, controlling the magnitude of an operation current flowing through the differential stage of the output amplifier using a bias voltage from the outside of the output amplifier such that the magnitude becomes large in the first half of one data period and the magnitude becomes small in the second half can be considered. For example, a bias circuit generating a bias voltage is disposed in a chip center part of a semiconductor IC chip as a display driver, and the bias voltage is supplied to each of output amplifiers disposed in a long-side direction of the semiconductor IC chip from this bias circuit through a bias line.

However, in accordance with high impedance according to resistance of the bias line and a gate capacitance of a transistor included in each output amplifier, a large deviation occurs between timings at which bias voltages are changed in a chip center part and a chip end part, and display blurs are generated.

Thus, as a method for shortening a timing difference of a bias voltage change between the chip center part and the chip end part, a display driver in which output amplifiers are divided into groups, and a sub-bias circuit generating a bias voltage is disposed for each group has been proposed (for example, see Patent Document 1 (Japanese Patent Laid-Open No. 2019-95545)). In the display driver disclosed in Patent Document 1, output amplifiers are divided into groups, and a sub-bias circuit generating a bias voltage is disposed for each group. Each sub-bias circuit receives a reference current of which a current value is fixed and a bias control signal from a main bias circuit disposed in a chip center part. Each sub-bias circuit generates a plurality of currents on the basis of the reference current and changes a combination of generated currents to be synthesized in accordance with a bias control signal to generate a desired synthesized current and generates a bias voltage corresponding to the value of the synthesized current.

However, in the display driver disclosed in Patent Document 1, in each of a plurality of sub-bias circuits connected to a main bias circuit, a circuit that adjusts the voltage value of a bias voltage in accordance with a bias control signal is disposed.

However, as the number of adjustment steps of a bias voltage is increased, the number of elements of each sub-bias circuit also increases, and there is a problem in that the power consumption also increases accordingly.

The disclosure provides an output amplifier circuit capable of controlling slew rates of a plurality of amplifiers by suppressing a chip occupancy area and power consumption and a display driver and a display device including this output amplifier circuit.

### SUMMARY

An output amplifier circuit according to the disclosure includes: 1st to n-th (here, n is an integer of 2 or more) amplifiers; 1st to K-th (here, K is an integer of 2 or more) sub-bias circuits configured to be disposed in correspondence with 1st to K-th amplifier groups acquired by dividing the 1st to n-th amplifiers for every predetermined number of amplifiers, generate a plurality of bias voltages for setting current values of operation currents of the amplifiers, and supply the bias voltages to amplifiers belonging to corresponding 1st to K-th amplifier groups; and a main bias circuit configured to receive control signals designating voltage values of the plurality of bias voltages, generate K currents having current values corresponding to the voltage values designated by the control signals, and supply the K currents to the 1st to K-th sub-bias circuits as 1st to K-th bias control currents, in which the 1st to K-th sub-bias circuits generate the plurality of bias voltages based on voltages acquired by performing current-to-voltage conversion on the bias control currents received by the sub-bias circuits among the 1st to K-th bias control currents.

A display driver according to the disclosure includes: a grayscale voltage generating circuit configured to generate 1st to n-th (here, n is an integer of 2 or more) grayscale voltages having voltage values corresponding to a luminance level of each pixel based on a video signal; and an output part configured to include the output amplifier circuit according to claim 1 and supply the 1st to n-th output voltages acquired by amplifying the 1st to n-th grayscale voltages using the 1st to n-th amplifiers of the output amplifier circuit to 1st to n-th data lines of a display panel.

A display device according to the disclosure includes: a display panel having 1st to n-th (here, n is an integer or 2 or more) data lines extending in a horizontal direction of a display screen; a grayscale voltage generating circuit configured to generate 1st to n-th (here, n is an integer of 2 or more) grayscale voltages having voltage values corresponding to a luminance level of each pixel based on a video signal; and an output part configured to include the output amplifier circuit according to claim 1 and supply the 1st to n-th output voltages acquired by amplifying the 1st to n-th grayscale voltages using the 1st to n-th amplifiers of the output amplifier circuit to the 1st to n-th data lines of the display panel.

### BRIEF DESCRIPTION OF THE DRAWINGS

FIG. 1 is a block diagram illustrating a configuration of an output amplifier circuit 100_1 as an output amplifier circuit according to a first embodiment of the disclosure.

FIG. 2 is a circuit diagram illustrating an internal configuration of an amplifier AP1 by extracting the amplifier AP1 from among amplifiers AP1 to APn.

FIG. 3 is a circuit diagram illustrating an internal configuration of each of sub-bias circuits SB1 to SB3.

FIG. 4 is a circuit diagram illustrating an internal configuration of a variable current source 11.

FIG. 5 is a layout diagram illustrating one example of an arrangement form of a main bias circuit MB_1, sub-bias circuits SB1 to SB3, and an output amplifier part OBLK_1 inside a semiconductor IC chip CHP.

FIG. 6 is a time chart illustrating waveforms of an output timing signal OCLK, a bias control signal PWRC, a variable bias control current Io, a bias voltage VBx, an input voltage V1, and an output voltage G1.

FIG. 7 is a time chart illustrating an example of changes of timings of the bias control signal PWRC, the variable bias control current Io, and the bias voltage VBx.

FIG. 8 is a circuit diagram illustrating a configuration of an output amplifier circuit 100_2 as an output amplifier circuit according to a second embodiment of the disclosure.

FIG. 9 is a circuit diagram illustrating an internal configuration of a current mirror circuit CM_2 and a bias control current generating part IG_2.

FIG. 10 is a time chart illustrating a switching control signal SWC that controls on/off of switching circuits SW12 and SW23.

FIG. 11 is a circuit diagram illustrating a configuration of an output amplifier circuit 100_3 as an output amplifier circuit according to a third embodiment of the disclosure.

FIG. 12 is a circuit diagram illustrating a configuration of each of the sub-bias circuits SB1a to SB3a.

FIG. 13 is a block diagram illustrating a configuration of a display device having a display driver including an output amplifier circuit 100_1, 1002, or 100_3.

### DESCRIPTION OF THE EMBODIMENTS

In the disclosure, a main bias circuit generates first to K-th bias control currents having current values corresponding to the voltage value of a bias voltage represented in a control signal and supplies the generated bias control currents to first to K-th sub-bias circuits. Each sub-bias circuit generates a plurality of bias voltages on the basis of a voltage acquired by performing a current-voltage conversion process on a received bias control current and supplies the generated voltages to an amplifier group corresponding thereto.

In this way, in performing control of slew rates of a plurality of amplifiers, in the disclosure, since an adjustment process for a bias voltage according to a control signal is performed by the main bias circuit, compared to a case in which this adjustment process is performed by each sub-bias circuit, a circuit area and power consumption can be reduced. Furthermore, a wiring supplying a control signal may be connected only to the main bias circuit, and thus, compared to a case in which this control signal is supplied to each sub-bias circuit, the number of wirings can be decreased.

According to the disclosure, an output amplifier circuit of which a chip occupancy area and power consumption are suppressed can be realized.

Hereinafter, embodiments of the disclosure will be described in detail with reference to the drawings.

### Embodiment 1

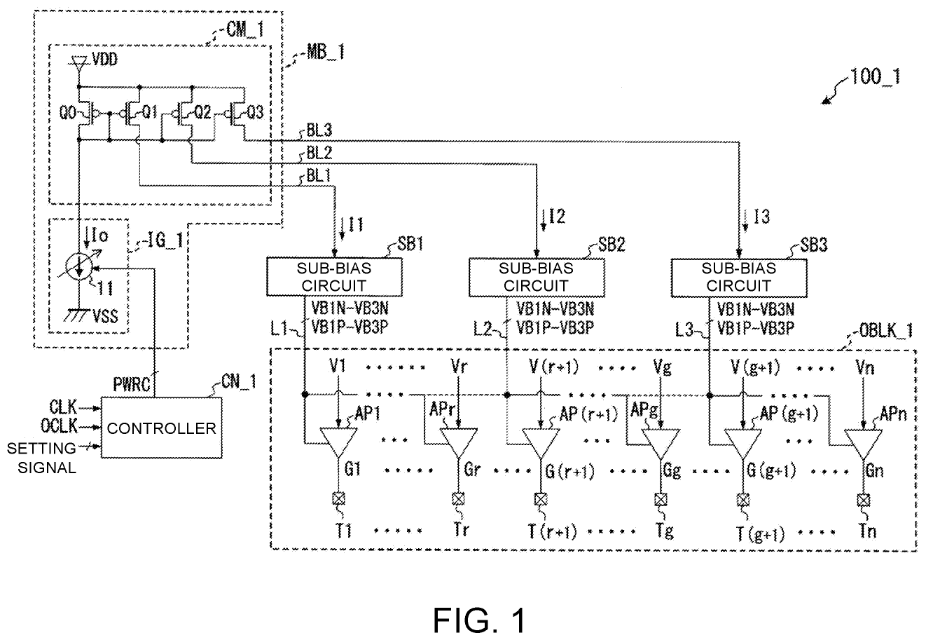

FIG. 1 is a block diagram illustrating a configuration of an output amplifier circuit 100_1 as an output amplifier circuit according to a first embodiment of the disclosure.

The output amplifier circuit 100_1 is a circuit that receives n (here, n is an integer of 2 or more) input voltages of which voltage values change for every predetermined data period and generates and outputs n output voltages acquired by amplifying the n input voltages.

The output amplifier circuit 100_1 is formed in a semiconductor IC chip and, as illustrated in FIG. 1, includes a main bias circuit MB_1, sub-bias circuits SB1 to SB3, a controller CN_1, and an output amplifier part OBLK_1.

The output amplifier part OBLK_1 includes amplifiers AP1 to APn that receive n input voltages V1 to Vn, generate n voltages acquired by respectively amplifying the input voltages as output voltages G1 to Gn, and output the generated output voltages through output terminals T1 to Tn of the semiconductor IC chip. In addition, each of the amplifiers AP1 to APn, for example, is formed from an operational amplifier of the same configuration, and operation currents caused to flow through a differential stage and a current mirror stage thereof are set in accordance with bias voltages VB1N to VB3N and VB1P to VB3P supplied from the sub-bias circuits SB1 to SB3. In accordance with this, each of the amplifiers AP1 to APn adjusts its output slew rate on the basis of the bias voltage group (VB1N to VB3N, VB1P to VB3P) described above.

The main bias circuit MB_1 includes a current mirror circuit CM_1 and a bias control current generating part IG_1.

The current mirror circuit CM_1 includes transistors Q0 and Q1 to Q3 of a p-channel type. Each of the transistors Q0 and Q1 to Q3 receives a power source voltage VDD using its source. A gate of each of the transistors Q1 to Q3 is connected to a gate and a drain of the transistor Q0. The bias control current generating part IG_1 includes a variable current source 11 that generates a variable bias control current Io be caused to flow through the drain of the transistor Q0.

In accordance with such a configuration, the current mirror circuit CM_1 supplies a bias control current I1 acquired by mirroring the variable bias control current Io flowing through the drain of the transistor Q0 from the drain of the transistor Q1 to the sub-bias circuit SB1 through a wiring BL1. In addition, the current mirror circuit CM_1 supplies a bias control current I2 acquired by mirroring this variable bias control current Io from the drain of the transistor Q2 to the sub-bias circuit SB2 through a wiring BL2. Furthermore, the current mirror circuit CM_1 supplies a bias control current I3 acquired by mirroring this variable bias control current Io from the drain of the transistor Q3 to the sub-bias circuit SB3 through a wiring BL3. In addition, a current mirror ratio of each of the bias control currents I1 to I3 to the variable bias control current Io is set to be common.

The controller CN_1 receives a clock signal CLK that serves as a base of timing generation of each control signal, an output timing signal OCLK setting the data period described above, and a setting signal and supplies a bias control signal PWRC designating the voltage value of a bias voltage to the variable current source 11 of the main bias circuit MB_1. The variable current source 11 changes the current value of the variable bias control current Io in accordance with such a bias control signal PWRC. In accordance with this, the main bias circuit MB_1 controls the current values of the bias control currents I1 to I3 supplied to each of the sub-bias circuits SB1 to SB3 in accordance with the bias control signal PWRC.

The sub-bias circuits SB1 to SB3 have the same internal configuration and are disposed to be respectively associated with first to third groups when the amplifiers AP1 to APn are divided into three groups. It is assumed that amplifiers AP1 to Apr (here, r is an integer less than n) belong to the first group, amplifiers AP(r+1) to APg (here, g is an integer greater than r and less than n) belong to the second group, and amplifiers AP(g+1) to APn belong to the third group.

The sub-bias circuit SB1 receives a bias control current I1 transmitted from the main bias circuit MB_1 through the wiring BL1. The sub-bias circuit SB1 generates bias voltages VB1N to VB3N and VB1P to VB3P having voltage values of magnitudes corresponding to the current value of the bias control current I1 and supplies the generated bias voltages to each of the amplifiers AP1 to Apr belonging to the first group through a first wiring group L1 formed from 6 wirings.

The sub-bias circuit SB2 receives a bias control current I2 transmitted from the main bias circuit MB_1 through the wiring BL2. The sub-bias circuit SB2 generates bias voltages VB1N to VB3N and VB1P to VB3P having voltage values of magnitudes corresponding to the current value of the bias control current I2 and supplies the generated bias voltages to each of the amplifiers AP(r+1) to Apg belonging to the second group through a second wiring group L2 formed from 6 wirings.

The sub-bias circuit SB3 receives a bias control current I3 transmitted from the main bias circuit MB_1 through the wiring BL3. The sub-bias circuit SB3 generates bias voltages VB1N to VB3N and VB1P to VB3P having voltage values of magnitudes corresponding to the current value of the bias control current I3 and supplies the generated bias voltages to each of the amplifiers AP(g+1) to Apn belonging to the third group through a third wiring group L3 formed from 6 wirings.

In addition, the wiring groups L1 to L3 described above may be electrically connected to each other.

Hereinafter, detailed configurations of the amplifiers AP1 to APn, the sub-bias circuits SB1 to SB3, and the variable current source 11 illustrated in FIG. 1 will be described.

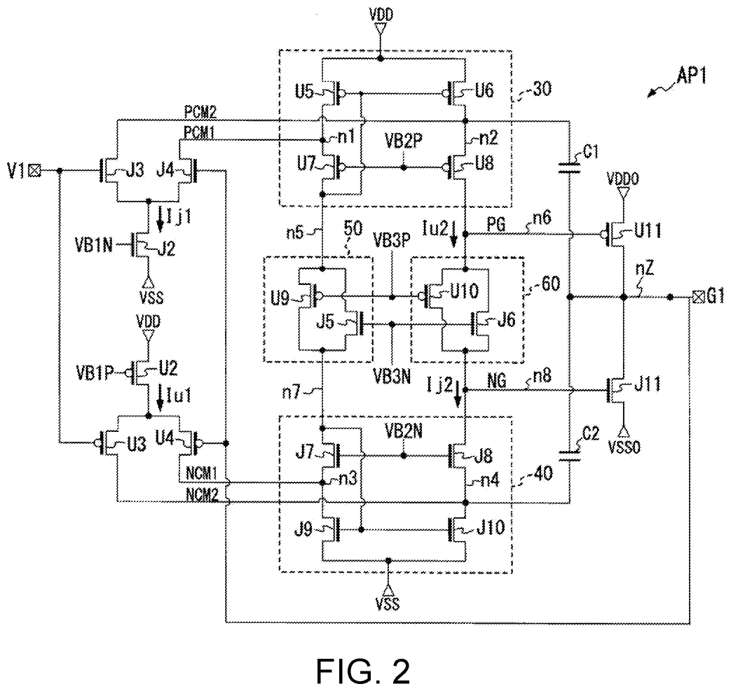

FIG. 2 is a circuit diagram illustrating an internal configuration of an amplifier AP1 by extracting the amplifier AP1 from among amplifiers AP1 to APn.

The amplifier AP1 has a differential stage including transistors U2 to U4 of a p-channel type and transistors J2 to J4 of an n-channel type, an output stage including a transistor U11 of the p-channel type and a transistor J11 of the n-channel type, cascode current mirror circuits 30 and 40, and floating current sources 50 and 60.

A power source voltage VDD is applied to a source of the transistor U2 of the differential stage, and a bias voltage VB1P is supplied to a gate thereof. The transistor U2 generates an operation current Iu1 having a current value corresponding to a bias voltage VB1P and supplies the generated operation current to a source of each of transistors U3 and U4. The transistor U3 receives an input voltage V1 using its gate. The transistor U4 receives an output voltage G1 that is an output of the amplifier AP1 using its gate. The transistors U3 and U4 generate differential output currents acquired by dividing an operation current Iu1 supplied from the transistor U2 into two parts with a voltage ratio between the input voltage V1 and the output voltage G1 as currents NCM1 and NCM2. The transistors U3 and U4 supply the currents NCM1 and NCM2 to nodes n3 and n4 of the cascode current mirror circuit 40 through drains thereof. In other words, the transistor U3 supplies the current NCM2 corresponding to the voltage value of the input voltage V1 to the node n4 of the cascode current mirror circuit 40. The transistor U4 supplies the current NCM1 corresponding to the voltage value of the output voltage G1 to the node n3 of the cascode current mirror circuit 40.

A ground voltage VSS is applied to a source of the transistor J2 of the differential stage, and a bias voltage VB1N is supplied to a gate thereof. A drain of the transistor J2 is connected to a source of each of the transistors J3 and J4. The transistor J2 generates an operation current Ij1 having a current value corresponding to the bias voltage VB1N and extracts this from the sources of the transistors J3 and J4. The transistor J3 receives an input voltage V1 using its gate. The transistor J4 receives an output voltage G1 using its gate. The transistors J3 and J4 generate differential output currents acquired by dividing an operation current Ij1 into two parts with a voltage ratio between the input voltage V1 received by each gate and an output voltage Y1 as currents PCM1 and PCM2. The transistor J3 extracts the current PCM2 corresponding to the input voltage V1 from the node n2 of the cascode current mirror circuit 30 and supplies this to the drain of the transistor J2. The transistor J4 extracts the current PCM1 corresponding to the output voltage G1 from the node n1 of the cascode current mirror circuit 30 and supplies this to the drain of the transistor J2.

In addition, in the differential stage described above, the current value of the operation current Iu1 is adjusted in accordance with the bias voltage VB1P, and the current value of the operation current Ij1 described above is adjusted in accordance with the bias voltage VB1N. In accordance with this, for example, the lower the voltage value of the bias voltage VB1P, a larger current is supplied to the nodes n3 and n4 of the cascode current mirror circuit 40. In addition, the higher the voltage value of the bias voltage VB1N, a larger current is drawn from the nodes n1 and n2 of the cascode current mirror circuit 30.

The cascode current mirror circuit 30 includes transistors U5 to U8 of the p-channel type, the cascode current mirror circuit 40 includes transistors J7 to J10 of the n-channel type. In addition, the floating current source 50 includes a transistor U9 of the p-channel type and a transistor J5 of the n-channel type, and the floating current source 60 includes a transistor U10 of the p-channel type and a transistor J6 of the n-channel type.

A power source voltage VDD is applied to a source of each of the transistors U5 and U6 of the cascode current mirror circuit 30, and gates thereof are connected to each other. A drain of the transistor U5 is connected to a source of the transistor U7 through the node n1. A drain of the transistor U6 is connected to a source of the transistor U8 through the node n2. A bias voltage VB2P is applied to both gates of the transistors U7 and U8. A drain of the transistor U7 is connected to gates of the transistors U5 and U6, a source of the transistor U9, and a drain of the transistor J5 of the floating current source 50 through the node n5.

A drain of the transistor U8 is connected to a source of the transistor U10 and a drain of the transistor J6 of the floating current source 60 through a node n6 as a driving node of a high electric potential side. A bias voltage VB3P is applied to a gate of each of the transistors U9 and U10, and a bias voltage VB3N is applied to a gate of each of the transistors J5 and J6. A drain of the transistor U9 and a source of the transistor J5 are connected to a drain of the transistor J7 of the cascode current mirror circuit 40 through a node n7. A drain of the transistor U10 and a source of the transistor J6 are connected to a drain of the transistor J8 of the cascode current mirror circuit 40 through a node n8 as a driving node of a low electric potential side.

A bias voltage VB2N is applied to a gate of each of the transistors J7 and J8. A source of the transistor J7 is connected to a drain of the transistor J9 through the node n3. A source of the transistor J8 is connected to a drain of the transistor J10 through a node n4. The ground voltage VSS is applied to a source of each of the transistors J9 and J10, and a gate of each of these transistors J9 and J10 is connected to the drain of the transistor J7.

In the cascode current mirror circuits 30 and 40 and the floating current sources 50 and 60 described above, an operation current Iu2 having a current value corresponding to a difference between the current PCM1 and the current PCM2 supplied from the differential stage flows through the node n6, and an operation current Ij2 having a current value corresponding to a difference between the current NCM1 and the current NCM2 supplied from the differential stage flows through the node n8.

In accordance with this, in the cascode current mirror circuits 30 and 40 and the floating current sources 50 and 60, by supplying the operation current Iu2 corresponding to the difference between the currents PCM1 and PCM2 to the node n6 or extracting the operation current Iu2 from the node n6, an output drive voltage PG of the high electric potential side is generated at the node n6. This output drive voltage PG is supplied to a gate of a transistor U11 of an output stage. In addition, in the cascode current mirror circuits 30 and 40 and the floating current sources 50 and 60, by supplying the operation current Ij2 corresponding to the difference between the currents NCM1 and NCM2 to the node n8 or extracting the operation current Ij2 from the node n8, an output drive voltage NG of the low electric potential side is generated at the node n8. This output drive voltage NG is supplied to a gate of the transistor J11 of the output stage.

The power source voltage VDD is applied to a source of the transistor U11 of the output stage, and, by generating a current corresponding to the output drive voltage PG received by the gate thereof and supplying this to an output node nZ, the voltage of the output node nZ is caused to increase. The ground voltage VSS is applied to a source of the transistor J11, and, by extracting a current corresponding to the output drive voltage NG received by a gate thereof from the output node nZ, the voltage of the output node nZ is caused to fall.

In accordance with operations of the transistors U11 and J11 described above, an output voltage G1 is generated at the output node nZ, and this is output through an output terminal. At this time, the output voltage G1 that has been output is fed back and supplied to the gate of the transistor U4 of the high electric potential side and the gate of the transistor J4 of the low electric potential side of the differential stage.

In addition, phase compensation capacitors C1 and C2 for causing the amplifier AP1 to perform a stable output operation are disposed. As one example of connection of the phase compensation capacitors, in FIG. 2, the phase compensation capacitor C1 is connected between the output node nZ and the node n2, and the phase compensation capacitor C2 is connected between the output node nZ and the node n4.

According to the configuration of the amplifier AP1 illustrated in FIG. 2, in accordance with magnitudes of bias voltages VB1N to VB3N and VB1P to VB3P, current values of operation currents Iu2 and Ij2 flowing through nodes n6 and n8 as driving nodes driving the transistors U11 and J11 of the output stage are adjusted. In accordance with this, the magnitude of the current that is transmitted from the output node nZ and is extracted from this output node nZ is changed, and the driving capability of the amplifier AP1 is adjusted. A change speed of the output voltage G1 at the time of the input voltage V1 of the amplifier AP1 being greatly changing, that is, a slew rate mainly depends on the operation currents Ij1 and Iu1 flowing through the differential stage. In simple terms, a slew rate can be regarded as a charging/discharging speed of the phase compensation capacitors C1 and C2 accompanying a change of the output voltage G1, and thus the larger the current values of the operation currents Ij1 and Iu1, the amplifier AP1 can have a higher slew rate with a higher driving capability.

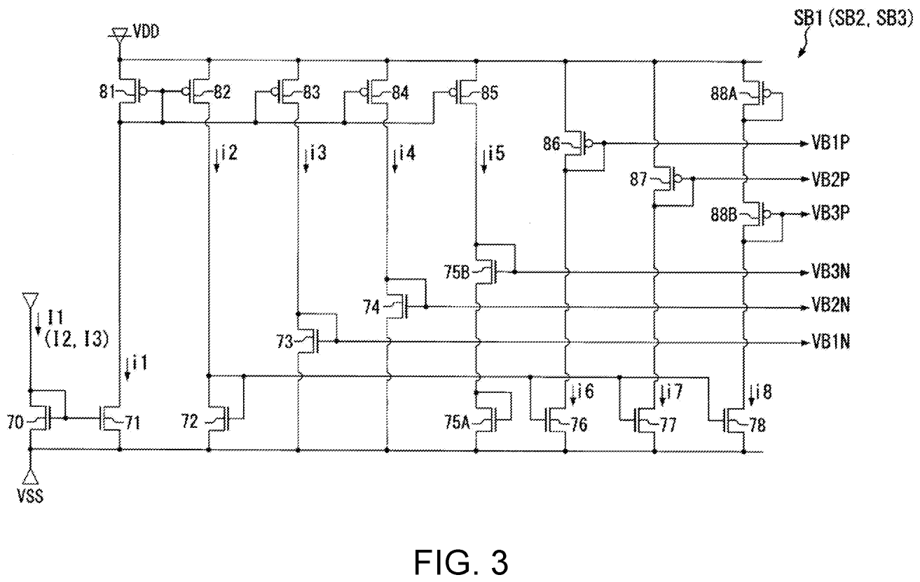

FIG. 3 is a circuit diagram illustrating an internal configuration of a sub-bias circuit SB1 by extracting the sub-bias circuit SB1 from among sub-bias circuits SB1 to SB3.

The sub-bias circuit SB1 has transistors 70 to 74, 75A, 75B, and 76 to 78 of the n channel type and transistors 81 to 87, 88A, and 88B of the p-channel type.

The transistors 70 and 71 configure a first current mirror circuit in which gates thereof are connected to each other, and the ground voltage VSS is applied to sources thereof. The first current mirror circuits (70 and 71) receive a bias control current I1 supplied from the main bias circuit MB_1 using the drain of the transistor 70.

The first current mirror circuit (70, 71) causes a mirror current i1 acquired by mirroring this bias control current I1 to flow through the drain of the transistor 81.

The transistors 81 to 85 configure a second current mirror circuit (81 to 85) in which gates thereof are connected to each other, and the power source voltage VDD is applied to sources thereof.

The second current mirror circuit (81 to 85) causes mirror currents i2 to i5 acquired by mirroring the mirror current i1 flowing through the transistor 81 to be transmitted from drains of the transistors 82 to 85.

The transistors 72 and 76 to 78 configure a third current mirror circuit (72 and 76 to 78) in which gates thereof are connected to each other, and the ground voltage VSS is applied to sources thereof.

The third current mirror circuit (72 and 76 to 78) causes mirror currents i6 to i8 acquired by mirroring the mirror current i2 transmitted from the drain of the transistor 82 to respectively flow through the transistors 76 to 78.

The transistor 73 is a diode-connected transistor in which a drain and a gate thereof are connected to each other. The transistor 73 receives the ground voltage VSS using its source and receives the copied current i3 described above using a drain and a gate thereof, thereby outputting a voltage generated at the drain and the gate as a bias voltage VB1N.

The transistor 74 is a diode-connected transistor in which a drain and a gate thereof are connected to each other. The transistor 74 receives the ground voltage VSS using its source and receives the mirror current i4 described above using a drain and a gate thereof, thereby outputting a voltage generated at the drain and the gate as a bias voltage VB2N.

The transistor 75A is a diode-connected transistor in which a drain and a gate thereof are connected to each other. The transistor 75A receives the ground voltage VSS using its source and has a drain connected to a source of the transistor 75B.

The transistor 75B is a diode-connected transistor in which a drain and a gate thereof are connected to each other. The transistor 75B receives the mirror current i5 described above using the drain and the gate thereof and outputs a voltage generated at the drain and the gate as a bias voltage VB3N.

The transistor 86 is a diode-connected transistor in which a drain and a gate thereof are connected to each other, and the drain is connected to the drain of the transistor 76. In accordance with the mirror current i6, which has flown through the transistor 76, flowing through its drain, the transistor 86 outputs the voltage generated at this drain as a bias voltage VB1P.

The transistor 87 is a diode-connected transistor in which a drain and a gate thereof are connected to each other, and the drain is connected to the drain of the transistor 77. In accordance with the mirror current i7, which has flown through the transistor 77, flowing through its drain, the transistor 87 outputs the voltage generated at this drain as a bias voltage VB2P.

The transistor 88A is a diode-connected transistor in which a drain and a gate thereof are connected to each other. The transistor 88A receives the power source voltage VDD using it source, and the drain is connected to a source of the transistor 88B.

The transistor 88B is a diode-connected transistor in which a drain and a gate thereof are connected to each other. The drain of the transistor 88B is connected to the drain of the transistor 78. In accordance with the mirror current i8, which has flown through the transistor 78, flowing through its drain, the transistor 88B outputs the voltage generated at this drain as a bias voltage VB3P.

In this way, the sub-bias circuit SB1 receives the bias control current I1 supplied from the main bias circuit MB_1 through the wiring BL1. Then, by converting each of the mirror currents i3 to i8 acquired by mirroring this bias control current I1 using the first to third current mirror circuits into a voltage using a diode-connected transistor, the sub-bias circuit SB1 acquires bias voltages VB1N to VB3N and VB1P to VB3P. In other words, by performing current-to-voltage conversion of the bias control current I1, the sub-bias circuit SB1 acquires the bias voltages VB1N to VB3N and VB1P to VB3P of 6 systems.

In addition, as described above, by employing a configuration similar to the configuration illustrated in FIG. 3 also in the sub-bias circuits SB2 and SB3, similar to the sub-bias circuit SB1, bias voltages VB1N to VB3N and VB1P to VB3P are generated on the basis of bias control currents I2 and I3 received thereby.

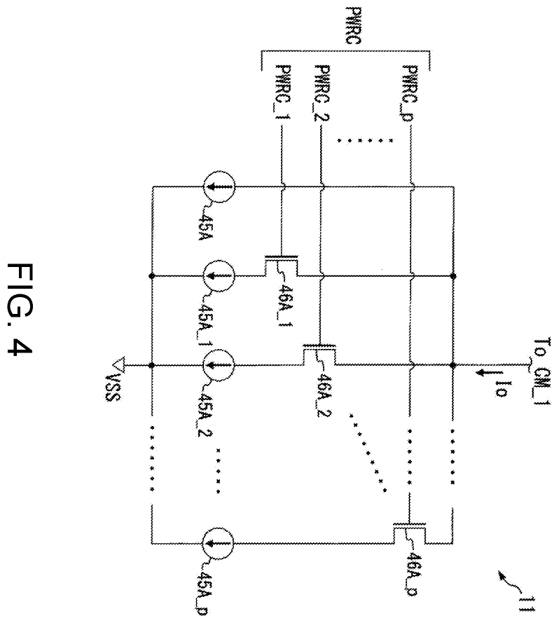

FIG. 4 is a circuit diagram illustrating an internal configuration of the variable current source 11 illustrated in FIG. 1.

As illustrated in FIG. 4, the variable current source 11 includes constant current sources 45A and 45A_1 to 45A_p (here, p is an integer of 2 or more) and transistors 46A_1 to 46A_p of the n-channel type as switching elements.

The constant current sources 45A and 45A_1 to 45A_p are connected in a parallel form between a power source terminal to which the ground voltage VSS is applied and the current mirror circuit CM_1 illustrated in FIG. 1. The transistors 46A_1 to 46A_p are disposed respectively in correspondence with the constant current sources 45A_1 to 45A_p. A source of each of the transistors 46A_1 to 46A_p is connected to a constant current source corresponding thereto, and each drain is connected to a drain of a transistor Q0 of the current mirror circuit CM_1.

Here, the bias control signal PWRC is formed from control signals PWRC_1 to PWRC_p of p systems having logic levels used for individually setting the transistors 46A_1 to 46A_p to an on-state or an off-state. These control signals PWRC_1 to PWRC_p are respectively supplied go gates of the transistors 46A_1 to 46A_p.

In accordance with the configuration illustrated in FIG. 4, a total current of currents transmitted from constant current sources connected to transistors set to the on-state among the transistors 46A_1 to 46A_p and the constant current source 45A becomes a variable bias control current Io.

Here, the output amplifier part OBLK_1 described above is disposed near an end part of a semiconductor IC chip such that the amplifiers AP1 to APn are aligned along a longer side of the semiconductor IC chip having a rectangular plane shape. In addition, each of the sub-bias circuits SB1 to SB3 is disposed near an amplifier group belonging to a group corresponding thereto among amplifier groups included in the output amplifier part OBLK_1, and the main bias circuit MB_1 is disposed in a center part of the semiconductor IC chip.

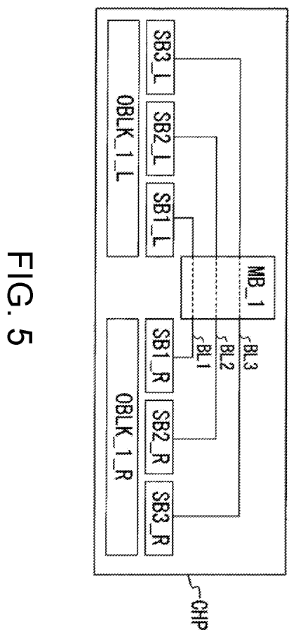

FIG. 5 is a layout diagram illustrating one example of an arrangement form of the main bias circuit MB_1, the sub-bias circuits SB1 to SB3, and the output amplifier part OBLK_1 inside a semiconductor IC chip CHP illustrated in FIG. 1.

In the layout illustrated in FIG. 5, the main bias circuit MB_1 is disposed in a center part of the semiconductor IC chip CHP. Then, the output amplifier part OBLK_1 and the sub-bias circuits SB1 to SB3 are divided into two parts and are disposed in a left and right areas of the main bias circuit MB_1.

In other words, the output amplifier part OBLK_1 is divided into output amplifier parts OBLK_1_L and OBLK_1_R, and the output amplifier part OBLK_1_L is disposed on a left side of the main bias circuit MB_1 near an end of one side of the semiconductor IC chip CHP.

Furthermore, the output amplifier part OBLK_1_R is disposed on a right side of the main bias circuit MB_1 near an end of one side of the semiconductor IC chip CHP.

In addition, the sub-bias circuit SB1 is divided into sub-bias circuits SB1_L and SB1_R, as illustrated in FIG. 5, the sub-bias circuit SB1_L is disposed near the output amplifier part OBLK_1_L, and the sub-bias circuit SB1_R is disposed near the output amplifier part OBLK_1_R. In addition, the sub-bias circuit SB2 is divided into sub-bias circuits SB2_L and SB2_R, as illustrated in FIG. 5, the sub-bias circuit SB2_L is disposed to a left neighbor of the sub-bias circuit SB1_L, and the sub-bias circuit SB2_R is disposed to a right neighbor of the sub-bias circuit SB1_R. Furthermore, the sub-bias circuit SB3 is divided into sub-bias circuits SB3_L and SB3_R, as illustrated in FIG. 5, the sub-bias circuit SB3_L is disposed to a left neighbor of the sub-bias circuit SB2_L, and the sub-bias circuit SB3_R is disposed to a right neighbor of the sub-bias circuit SB2_R.

In addition, as illustrated in FIG. 5, the sub-bias circuits SB1_L and SB1_R are connected to the main bias circuit MB_1 disposed in the center part of the semiconductor IC chip CHP using a wiring BL1. In addition, as illustrated in FIG. 5, the sub-bias circuits SB2_L and SB2_R are connected to this main bias circuit MB_1 using a wiring BL2, and the sub-bias circuits SB3_L and SB3_R are connected to this main bias circuit MB_1 using a wiring BL3.

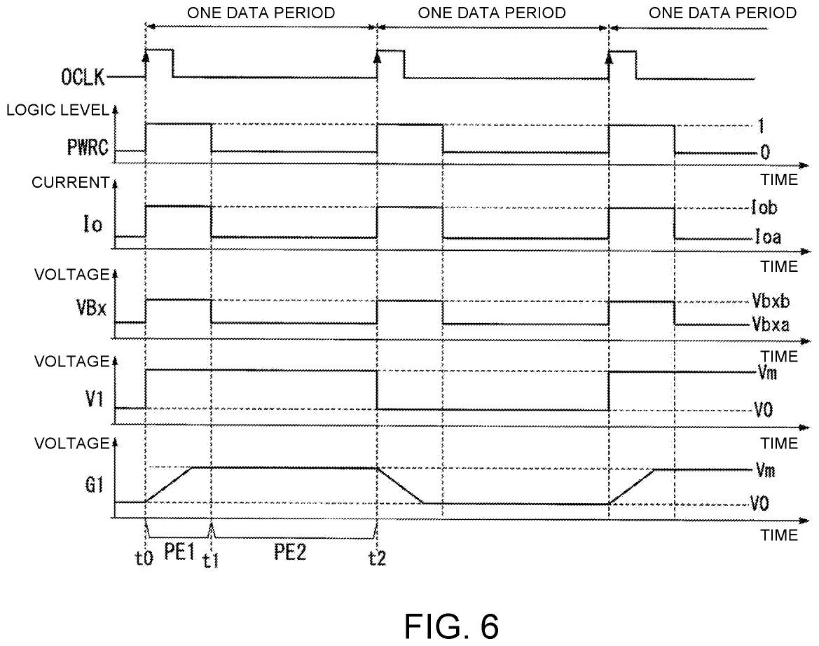

Next, an internal operation of the output amplifier circuit 100_1 will be described with reference to FIG. 6.

FIG. 6 is a time chart illustrating an output timing signal OCLK, a bias control signal PWRC, a variable bias control current Io, a bias voltage VBx, an input voltage V1 applied to the amplifier AP1, and an output voltage G1 of the amplifier AP1. The bias voltage VBx illustrated in FIG. 6 collectively represents bias voltages VB1N to VB3N and VB1P to VB3P respectively generated by the sub-bias circuits SB1 to SB3.

Over a predetermined first period PE1 from a time point t0 of a rising edge of the output timing signal OCLK illustrated in FIG. 6, the controller CN_1 generates a bias control signal PWRC of logic level 1 designating a predetermined first voltage value enabling an amplifier to have a high driving capability as a voltage value of a bias voltage and supplies this to the bias control current generating part IG_1. The first period PE1, for example, is set in accordance with a clock number of a clock signal CLK designated using a setting signal.

As illustrated in FIG. 6, the bias control current generating part IG_1 generates a variable bias control current Io having a predetermined high current value Iob over the first period PE1 in accordance with this bias control signal PWRC of logic level 1 and causes this to flow through the current mirror circuit CM_1. Thus, the current mirror circuit CM_1 generates bias control currents I1 to I3 of three systems acquired by mirroring this variable bias control current Io having the high current value Iob and respectively supplies the generated bias control currents to the sub-bias circuits SB1 to SB3 through the wirings BL1 to BL3.

By performing current-to voltage conversion for the received bias control currents (I1, I2, and I3), the sub-bias circuits SB1 to SB3, as illustrated in FIG. 6, generate bias voltages VBx (VB1N to VB3N and VB1P to VB3P) having a high voltage value Vbxb and supply the generated bias voltages to amplifier groups belonging to groups thereof.

Then, over a second period PE2 from a time point t1 at which this first period PE1 has elapsed to a time point t2 of a rising edge of a next clock signal CLK, the controller CN_1 generates a bias control signal PWRC of logic level 0 designating a predetermined second voltage value enabling an amplifier to have a low driving capability as the voltage value of a bias voltage and supplies this to the bias control current generating part IG_2.

In accordance with this bias control signal PWRC of logic level 0, the bias control current generating part IG_1, as illustrated in FIG. 6, generates a variable bias control current Io having a low current value Ioa smaller than the high current value Iob over the second period PE2 and causes this to flow through the current mirror circuit CM_1. Thus, the current mirror circuit CM_1 generates bias control currents I1 to I3 of three systems acquired by mirroring this variable bias control current Io having the low current value Ioa and respectively transmits the generated bias control currents to the sub-bias circuits SB1 to SB3 through the wirings BL1 to BL3.

By performing current-to voltage conversion for the received bias control currents (I1, I2, and I3), the sub-bias circuits SB1 to SB3, as illustrated in FIG. 6, generate low bias voltages VBx (VB1N to VB3N and VB1P to VB3P) having a low voltage value Vbxa lower than the high voltage value Vbxb and supply the generated bias voltages to amplifier groups belonging to groups thereof.

As illustrated in FIG. 6, according to the operations described above, an operation current flowing through the inside of each amplifier AP during the first period PE1 from the rising edge time point t0 of the output timing signal OCLK is higher than an operation current flowing through the inside of each amplifier AP in a second period PE2 following this first period PE1.

In accordance with this, during a section of a rising edge or a falling edge of an output voltage (for example, the output voltage G1 illustrated in FIG. 6) in which a high-speed response is required in a case in which a change of an input voltage is large, the slew rate of the amplifier AP becomes high, and thus, a rising edge time or a falling edge time of an output voltage output from the amplifier AP is shortened.

On the other hand, in the second period PE2 from an end time point t1 of the first period PE1 to a time point t2 of a rising edge of a next clock signal CLK, a voltage change of the output voltage G1 is sufficiently small, and thus, by causing an operation current flowing through the inside of each amplifier to be smaller than the operation current flowing through the inside of each amplifier AP in the first period PE1, the driving capability of each amplifier AP can be lowered.

In accordance with this, in a voltage-value constant section (PE2) of the output voltage in which the driving capability can be suppressed, power consumption consumed by the amplifier AP becomes small.

In this way, in the output amplifier circuit 100_1 illustrated in FIG. 1, by adjusting voltage values of bias voltages determining current values of operation currents flowing through the amplifiers AP1 to APn in accordance with a bias control signal PWRC, the driving capability of each amplifier can be controlled (changed). Thus, according to the operation of such an output amplifier circuit 100_1, a high-speed responding process can be performed with low power consumption.

Here, in the output amplifier circuit 100_1, adjustment of voltage values of bias voltages is performed altogether by the main bias circuit MB_1. In other words, the main bias circuit MB_1 receives a bias control signal PWRC designating a voltage value of a bias voltage and generates a variable bias control current Io having a current value corresponding to the voltage value of the bias voltage represented in this bias control signal PWRC. Then, the main bias circuit MB_1 supplies bias control currents I1 to I3 acquired by mirroring such a variable bias control current Io in correspondence with the number (three) of the sub-bias circuits SB1 to SB3 to the sub-bias circuits SB1 to SB3. At this time, the sub-bias circuits SB1 to SB3, by performing current-voltage conversion processes on the bias control currents received thereby, acquire bias voltages (VB1N to VB3N and VB1P to VB3P) having voltage values corresponding to the driving capability designated by the bias control signal PWRC.

In this way, in the output amplifier circuit 100_1, the main bias circuit MB_1 generates bias control currents I1 to I3 having current values corresponding to the voltage value of the bias voltage represented in the bias control signal PWRC and respectively supplies the bias control currents to the sub-bias circuits SB1 to SB3. The sub-bias circuits SB1 to SB3 generate bias voltage groups (VB1N to VB3N and VB1P to VB3P) on the basis of voltages acquired by performing current-to-voltage conversion processes on bias control currents received thereby and supplies them to amplifier groups [AP1 to APr, AP(r+1) to APg, AP(g+1) to APn] corresponding thereto.

In other words, in the output amplifier circuit 100_1, in controlling the driving capabilities of the amplifiers AP1 to APn, the process of adjusting bias voltages according to the bias control signal PWRC is performed by the main bias circuit MB_1. In accordance with this, compared to a case in which the process of adjusting a bias voltage is performed by each of the sub-bias circuits SB1 to SB3, the circuit area and the power consumption can be reduced. Furthermore, according to such a configuration, a wiring supplying a bias control signal PWRC may be connected only to the main bias circuit, and thus, compared to a case in which wirings for supplying the bias control signal PWRC are disposed in the sub-bias circuits SB1 to SB3, the number of wirings can be decreased.

Thus, according to the output amplifier circuit 1001, the chip occupancy area and the power consumption can be reduced.

### Embodiment 2

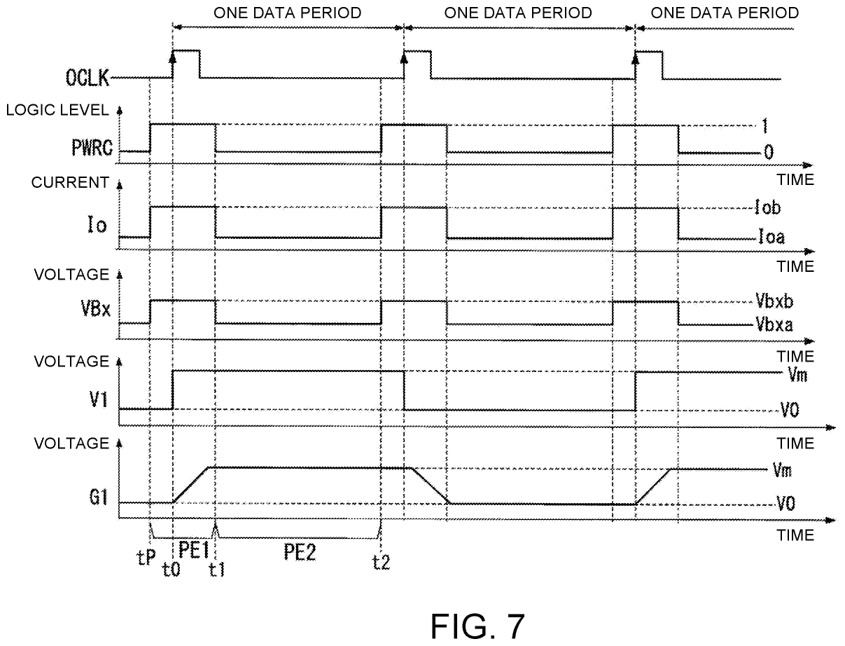

FIG. 7 is a time chart illustrating an example of changes of timings of the bias control signal PWRC, the variable bias control current Io, and the bias voltage VBx illustrated in FIG. 6.

In FIG. 7, the controller CN_1 supplies a bias control signal PWRC for switching the current value of the variable bias control current Io from a current value Ioa to a current value Iob higher than the current value Ioa to the main bias circuit MB_1 at a time point tP that is a predetermined time before a start time point t0 of one data period.

In accordance with this, even in a case in which an output voltage of each amplifier slightly changes in accordance with the influence of an external noise (for example, a coupling noise accompanying a change of a gate voltage) in the second period PE2 in which the bias voltage is low, the output voltage can be recovered to a desired voltage value at the predetermined time before the end of the one data period.

In addition, since each amplifier is set to a high slew rate state in accordance with a bias control signal PWRC from a time before the start of the one data period, each amplifier operates with a high slew rate without causing a delay with respect to a change of the output voltage immediately after start of one data period. In other words, according to the operations illustrated in FIG. 7, the influence of a response delay until a bias voltage is actually changed after the adjustment process for changing the slew rate of the amplifier starts in accordance with a bias control signal PWRC can be eliminated.

### Embodiment 3

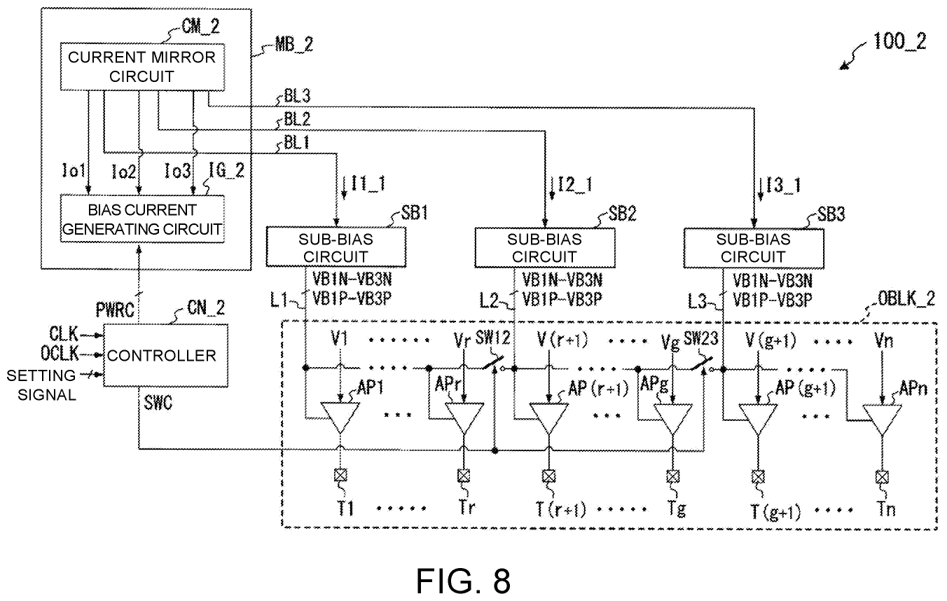

FIG. 8 is a circuit diagram illustrating a configuration of an output amplifier circuit 100_2 as an output amplifier circuit according to the second embodiment of the disclosure.

In a case in which bias voltage control among first to third groups dividing amplifiers AP1 to APn into three groups is performed for each group, the output amplifier circuit 100_2 adds a function of equalizing bias voltages between groups immediately before the end of one data period to the output amplifier circuit 100_1. For the time of the end of one data period at which a recording voltage for each display cell of a display panel is finalized, in a predetermined period before that, by equalizing bias voltages of all the amplifiers AP1 to Apn, an effect of suppressing an occurrence of display blurring due to a voltage difference of bias voltages between groups is acquired. In addition, as a case in which bias voltage control is individually performed for each group, for example, there is a case in which a timing of start of one data period is slightly delayed in units of a predetermined number of amplifiers or in units of amplifiers of the first to third groups in accordance with a waveform delay of a scanning signal of the display panel.

As illustrated in FIG. 8, the output amplifier circuit 1002 employs a main bias circuit MB_2, a controller CN_2, and an output amplifier part OBLK_2 in place of the main bias circuit MB_1, the controller CN_1, and the output amplifier part OBLK_1 illustrated in FIG. 1. Internal configurations and operations of sub-bias circuits SB1 to SB3 are the same as those illustrated in FIG. 1.

The main bias circuit MB_2 illustrated in FIG. 8 employs a current mirror circuit CM_2 and a bias control current generating part IG_2 in place of the current mirror circuit CM_1 and the bias control current generating part IG_1 illustrated in FIG. 1.

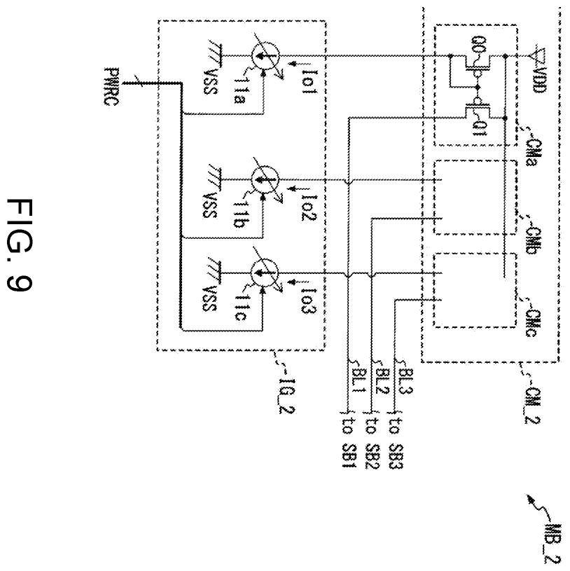

FIG. 9 is a circuit diagram illustrating an internal configuration of the current mirror circuit CM_2 and the bias control current generating part IG_2.

As illustrated in FIG. 9, the current mirror circuit CM_2 includes independent current mirror circuits CMa to CMc of three systems each formed from the transistors Q0 and Q1 illustrated in FIG. 1. The bias control current generating part IG_2 includes variable current sources 11a to 11c respectively connected to transistors Q0 of the current mirror circuits CMa to CMc.

The controller CN_2 supplies bias control signals PWRC individually controlling the variable current sources 11a to 11c to the variable current sources 11a to 11c of the bias control current generating part IG_2 at the timing of a clock signal CLK.

In addition, the main bias circuit MB_2 individually generating bias control currents I1 to I3 of three systems may have a configuration in which three variable current sources that are individually controlled using bias control signals PWRC with reference to a power source voltage VDD are included, and output currents of these three variable current sources are set as bias control currents I1 to I3 as they are instead of the configuration illustrated in FIG. 9.

In the output amplifier part OBLK_2, similar to the output amplifier part OBLK_1 illustrated in FIG. 1, together with amplifiers AP1 to APn, first to third wiring groups L1 to L3 connecting these amplifier groups and sub-bias circuits SB1 to SB3 are disposed.

In addition, in the output amplifier part OBLK_2, a switching circuit SW12 formed from 6 switching elements each electrically connecting a first wiring group L1 and a second wiring group L2 that supply the same bias voltage is disposed.

Furthermore, in the output amplifier part OBLK_2, a switching circuit SW23 formed from 6 switching elements each electrically connecting a second wiring group L2 and a third wiring group L3 that supply the same bias voltage is disposed.

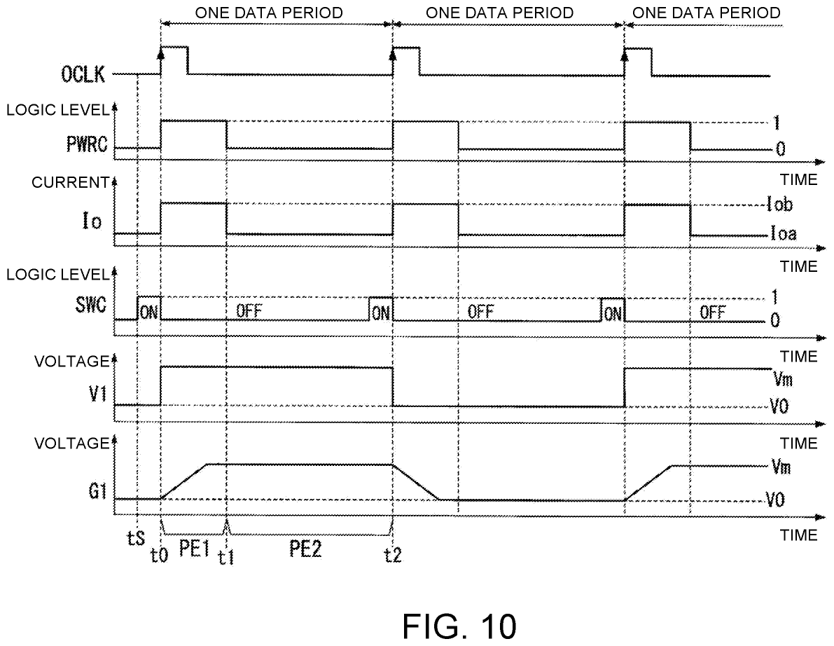

Here, as illustrated in a time chart illustrated in FIG. 10, the controller CN_2, for each data period, supplies a switching control signal SWC setting all the switching elements of the switching circuits SW12 and SW23 to an on state only between a predetermined period (tS-t0) of a second half of a second period PE2 in the data period and setting the switching elements to an off state in the other period to these switching circuits SW12 and SW23.

In accordance with such a configuration, for each of first to third groups acquired by dividing amplifiers AP1 to APn into three groups, in individually supplying bias voltage groups (VB1N to VB3N and VB1P to VB3P), bias voltage between groups can be equalized in a predetermined period before the end of one data period. In addition, in a case in which the timing of start of one data period is slightly delayed in units of amplifiers of the first to third groups, the timing of end of the on-period of all the switching elements of the switching circuits SW12 and SW23 are set to be before the timing of start of one data period of a group for which start of a next one data period is the earliest.

In addition, in a case in which on-resistance of 6 switching elements included in each of the switching circuits 12 and 23 is high, each thereof may be constantly maintained to be in the on state. Furthermore, in this case, 6 high-resistance elements may be employed in place of the 6 switching elements included in each of the switching circuits 12 and 23.

### Embodiment 4

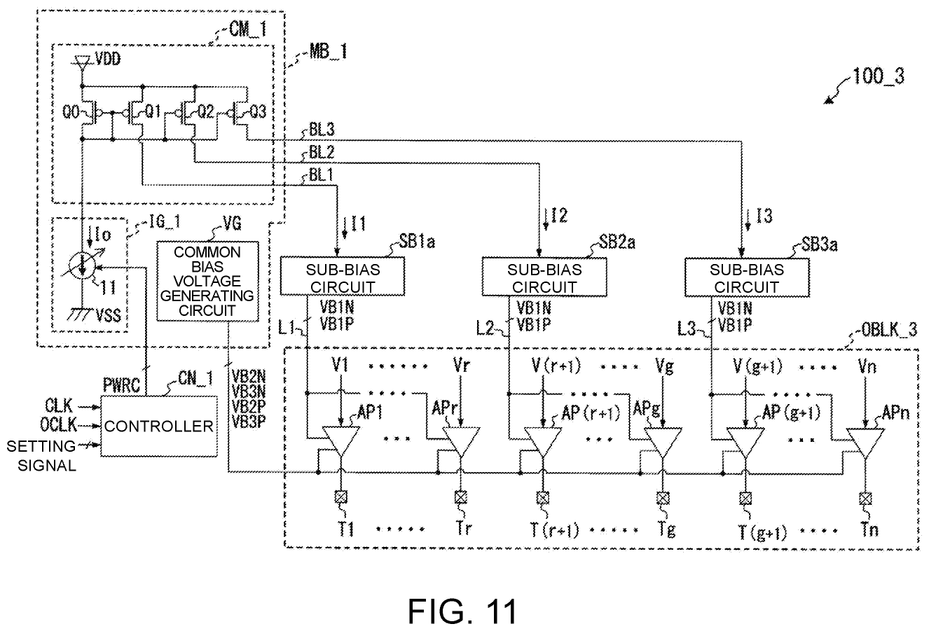

FIG. 11 is a circuit diagram illustrating a configuration of an output amplifier circuit 100_3 as an output amplifier circuit according to a third embodiment of the disclosure.

In addition, other configurations of the output amplifier circuit 100_3 except for a configuration in which sub-bias circuits SB1a to SB3a are employed in place of the sub-bias circuits SB1 to SB3, and a common bias voltage generating circuit VG is newly disposed in the main bias circuit MB_1 are the same as those illustrated in FIG. 1.

The output amplifier circuit 100_3 generates only bias voltages VB1N and VB1P, for example, controlling tail currents of a differential pair directly relating to a driving capability among a bias voltage group supplied to each amplifier AP in each of the sub-bias circuits SB1a to SB3a using a variable bias control current Io. At this time, the other bias voltage groups are generated by the common bias voltage generating circuit VG.

In other words, the common bias voltage generating circuit VG generates bias voltages VB2N, VB3N, VB2P, and VB3P of which voltage values are constant and supplies the generated bias voltages to all the amplifiers AP1 to APn.

Thus, each of the sub-bias circuits SB1a to SB3a does not need to generate the bias voltages VB2N, VB3N, VB2P, and VB3P.

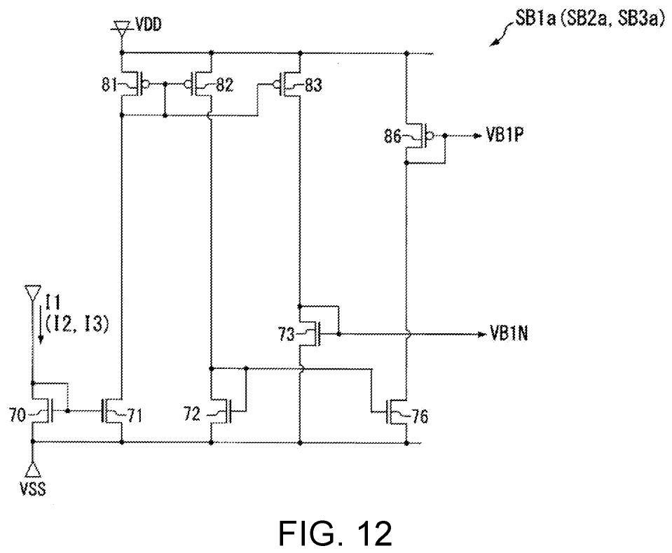

Thus, as illustrated in FIG. 12, each of the sub-bias circuits SB1a to SB3a has a configuration acquired by omitting transistors 74, 75A, 75B, 77, 78, 84, 85, 87, 88A, and 88B engaged in generation of bias voltages VB2N, VB3N, VB2P, and VB3P from the configuration illustrated in FIG. 3. In accordance with this, by decreasing the number of elements configuring the sub-bias circuits, and the area can be saved.

In addition, in the output amplifier circuits 100_1 to 100_3 of the embodiments 1 to 4 described above, the amplifiers AP1 to APn are divided into the first to third groups, and bias voltages of respective groups are generated by the three sub-bias circuits SB1 to SB3. However, the number of groups of the amplifiers AP1 to APn and the number of sub-bias circuits are not limited to three and may be two or four or more.

In short, as output amplifier circuits according to the disclosure, for the 1st to n-th amplifiers, the 1st to K-th (here, K is an integer of 2 or more) sub-bias circuits and a main bias circuit as below may be included.

The 1st to K-th sub-bias circuits (for example, SB1 to SB3) are disposed in correspondence with 1st to K-th (here, K is an integer of 2 or more) amplifier groups acquired by dividing the 1st to n-th amplifiers (AP1 to APn) for every predetermined number of amplifiers [for example, AP1 to APr, AP(r+1) to APg, and AP(g+1) to APn]. Each of the 1st to K-th sub-bias circuits generates a plurality of bias voltages (for example, VB1N and VB1P, or VB1N to VB3N and VB1P to VB3P) used for setting current values of operation currents of amplifiers and supplies the generated bias voltages to each amplifier belonging to a corresponding amplifier group.

On the other hand, the main bias circuit (MB_1 and MB_2) receives a control signal (PWRC) designating voltage values of a plurality of bias voltages, generates K currents having current values corresponding to the voltage values designated using this control signal, and supplies them to the 1st to K-th sub-bias circuits (for example, SB1 to SB3) as 1st to K-th bias control currents (for example, I1 to I3). In addition, each of the 1st to K-th sub-bias circuits generates the plurality of bias voltages described above on the basis of voltages acquired by performing current-to-voltage conversion of the bias control currents received thereby among the 1st to K-th bias control currents.

### Embodiment 5

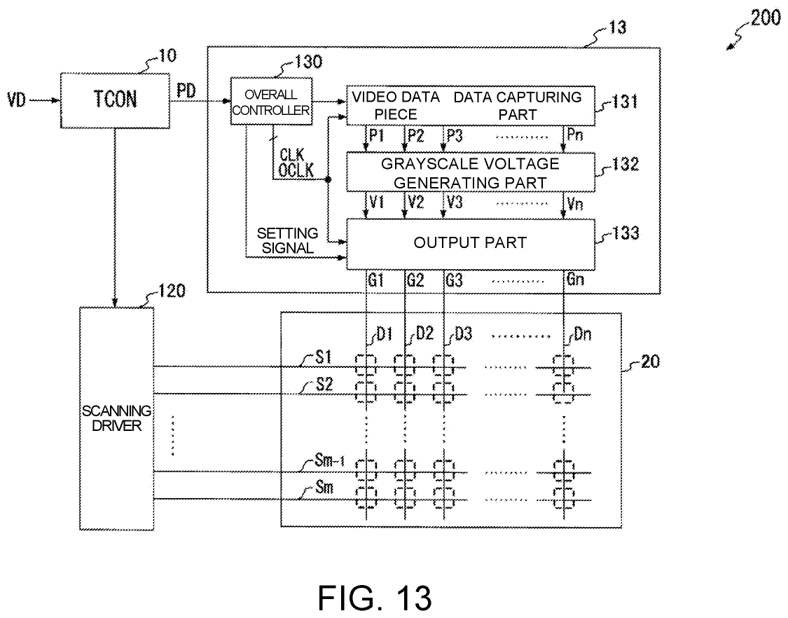

FIG. 13 is a block diagram illustrating a configuration of a display device 200 having a display driver including an output driver circuit according to the disclosure. As illustrated in FIG. 13, the display device 200 includes a timing controller (hereinafter, referred to as TCON) 10, a scanning driver 12, a data driver 13, and a display panel 20.

The display panel 20, for example, is formed from an organic EL panel, a liquid crystal display panel, or the like. In the display panel 20, scanning lines S1 to Sm (here, m is an integer or 2 or more) extending in a horizontal direction of a two-dimensional screen and data lines D1 to Dn (here, n is an integer of 2 or more) extending in a vertical direction of the two-dimensional screen are formed. In an area (an area surrounded by a broken line) of each intersection of a horizontal scanning line and a data line, a display cell is formed.

In addition, the horizontal scanning lines S1 to Sm are connected to a scanning driver 12, and the data lines D1 to Dn are connected to a data driver 13.

The TCON 10 generates a scanning timing control signal on the basis of a video signal VD and supplies the generated scanning timing control signal to the scanning driver 120. In addition, the TCON 10 generates an image data signal PD including various control signals such as a clock signal and a data capture signal and various setting signals together with a column of pixel data pieces representing a luminance level of a pixel, for example, using a luminance grayscale of 8 bits on the basis of the video signal VD and supplies them to the data driver 13.

The scanning driver 12 sequentially applies a scanning pulse signal to the scanning lines S1 to Sm of the display panel 20 on the basis of a scanning timing control signal supplied from the TCON 10.

The data driver 13, for example, is formed in a semiconductor integrated circuit (IC) chip and includes an overall controller 130, a data capturing part 131, a grayscale voltage generating part 132, and an output part 133. In addition, particularly for a mobile use and the like, a data driver reading the TCON 10 is also present. In addition, in a case in which the display panel 20 is a large screen, a plurality of data drivers 13 may be included.

The overall controller 130 of the data driver 13 receives an image data signal PD, divides the image data signal PD into an image data piece, a clock signal, various control signals, and various setting signals, and supplies them to respective blocks corresponding thereto inside the data driver 13. The data capturing part 131 receives an image data piece, a clock signal CLK, and an output timing signal OCLK from the overall controller 130, shifts the image data piece in accordance with the clock signal CLK, and captures pixel data pieces corresponding to one horizontal scanning line, that is, n pixel data pieces, on the basis of the output timing signal OCLK. The data capturing part 131 sets n pixel data pieces that have been captured as pixel data P1 to Pn and supplies this pixel data P1 to Pn to the grayscale voltage generating part 132, for example, at the timing of a rising edge of the output timing signal OCLK.

The grayscale voltage generating part 132 converts pixel data P1 to Pn supplied from the data capturing part 131 into grayscale voltages V1 to Vn having voltage values corresponding to luminance levels thereof and supplies the grayscale voltages to the output part 133.

The output part 133 includes the output amplifier circuit 1001, 100_2, or 100_3 described above, receives the grayscale voltages V1 to Vn as input voltages V1 to Vn, and supplies output voltages G1 to Gn acquired by individually amplifying the grayscale voltages using the amplifiers AP1 to APn to the data lines D1 to Dn of the display panel 20.

What is claimed is:

1. An output amplifier circuit, comprising:
1st to n-th (here, n is an integer of 2 or more) amplifiers;
1st to K-th (here, K is an integer of 2 or more) sub-bias circuits configured to be disposed in correspondence with 1st to K-th amplifier groups acquired by dividing the 1st to n-th amplifiers for every predetermined number of amplifiers, generate a plurality of bias voltages for setting current values of operation currents of the amplifiers, and supply the bias voltages to amplifiers belonging to corresponding 1st to K-th amplifier groups; and
a main bias circuit configured to receive control signals designating voltage values of the plurality of bias voltages, generate K currents having current values corresponding to the voltage values designated by the control signals, and supply the K currents to the 1st to K-th sub-bias circuits as 1st to K-th bias control currents,
wherein the 1st to K-th sub-bias circuits generate the plurality of bias voltages based on voltages acquired by performing current-to-voltage conversion on the bias control currents received by the sub-bias circuits among the 1st to K-th bias control currents.

2. The output amplifier circuit according to claim 1,
wherein the 1st to K-th sub-bias circuits have 1st to K-th bias voltage wiring groups supplying the plurality of bias voltages generated by the sub-bias circuits to the 1st to K-th amplifier groups, and
wherein the same bias voltage wirings among the 1st to K-th bias voltage wiring groups are electrically connected to each other between the sub-bias circuits.

3. The output amplifier circuit according to claim 2,
wherein the same bias voltage wirings among the 1st to K-th bias voltage wiring groups are connected through a switch between the sub-bias circuits, and
the output amplifier circuit further comprises a controller configured to supply a switching control signal periodically controlling the switch to be in an on state only in a predetermined period to the switch.

4. The output amplifier circuit according to claim 1,
wherein the operation current is set in each of the 1st to n-th amplifiers in accordance with reception of a common bias voltage different from the plurality of bias voltages together with the plurality of bias voltages, and
wherein the main bias circuit includes a common bias voltage generating circuit generating the common bias voltage of which a voltage value is fixed and supplying the common bias voltage to the 1st to n-th amplifiers.

5. The output amplifier circuit according to claim 1,
wherein the 1st to n-th amplifiers receive 1st to n-th input voltages for every data period of a predetermined period and generate 1st to n-th output voltages acquired by amplifying the 1st to n-th input voltages, and
wherein the main bias circuit, for every data period, in a first period immediately after start of the data period, supplies the bias control current having a current value corresponding to a first voltage value to the 1st to K-th sub-bias circuits for setting voltage values of the plurality of bias voltages to the first voltage value increasing the operation currents of the 1st to n-th amplifiers and, in a second period following the first period, supplies the bias control current having a current value corresponding to a second voltage value to the 1st to K-th sub-bias circuits for setting the voltage values of the plurality of bias voltages to the second voltage value decreasing the operation currents of the 1st to n-th amplifiers.

6. The output amplifier circuit according to claim 5, wherein the main bias circuit, for every data period, in a third period following the second period, supplies the bias control current having a current value corresponding to the first voltage value to the 1st to K-th sub-bias circuits for setting the voltage values of the plurality of bias voltages to the first voltage value increasing the operation currents of the 1st to n-th amplifiers.

7. A display driver comprising:
a grayscale voltage generating circuit configured to generate 1st to n-th (here, n is an integer of 2 or more) grayscale voltages having voltage values corresponding to a luminance level of each pixel based on a video signal; and
an output part configured to include the output amplifier circuit according to claim 1 and supply the 1st to n-th output voltages acquired by amplifying the 1st to n-th grayscale voltages using the 1st to n-th amplifiers of the output amplifier circuit to 1st to n-th data lines of a display panel.

8. A display device comprising:
a display panel having 1st to n-th (here, n is an integer or 2 or more) data lines extending in a horizontal direction of a display screen;
a grayscale voltage generating circuit configured to generate 1st to n-th grayscale voltages having voltage values corresponding to a luminance level of each pixel based on a video signal; and
an output part configured to include the output amplifier circuit according to claim 1 and supply the 1st to n-th output voltages acquired by amplifying the 1st to n-th grayscale voltages using the 1st to n-th amplifiers of the output amplifier circuit to the 1st to n-th data lines of the display panel.
